(19) United States
(12) Patent Application Publication
(10) Pub. No.: US 2019/0119786 A1
(43) Pub. Date: Apr. 25, 2019

(54) COPPER ALLOY BACKING TUBE AND METHOD OF MANUFACTURING COPPER ALLOY BACKING TUBE

(71) Applicant: MITSUBISHI MATERIALS CORPORATION, Tokyo (JP)

(72) Inventors: Shinji Kato, Sanda-shi (JP); Masanori Yosuke, Tokyo (JP); Akifumi Mishima, Sanda-shi (JP); Michiaki Ohto, Osaka (JP)

(21) Appl. No.: 16/090,886

(22) PCT Filed: Apr. 11, 2017
(86) PCT No.: PCT/JP2017/014815

§ 371 Date: Oct. 3, 2018

(30) Foreign Application Priority Data
Apr. 12, 2016 (JP) 2016-079420

(51) Int. Cl. C22C 9/06; C22C 9/02; C22F 1/08; C23C 14/34; B21C 23/00; B21C 23/08

(52) U.S. Cl. CPC C22C 9/06; C22C 9/02; B21C 23/085; C23C 14/3414; B21C 23/002; C22F 1/08

(57) ABSTRACT

There is provided a copper alloy backing tube formed of a copper alloy having a composition containing 0.10 mass % or more and 0.30 mass % or less of Co, 0.030 mass % or more and 0.10 mass % or less of P, 0.01 mass % or more and 0.50 mass % or less of Sn, 0.02 mass % or more and 0.10 mass % or less of Ni, and 0.01 mass % or more and 0.10 mass % or less of Zn. A copper balance containing impurities. A mass ratio [Co]/[P] is set to be within a range of 3.0 or higher and 6.0 or lower. A thermal conductivity is set to 250 W/(m·K) or higher. A micro-Vickers hardness after a heating treatment is performed in a condition of being held for one hour at 250° C. is 100 Hv or higher, and a decrease rate from a hardness before the heating treatment is set to 5% or less.

### TECHNICAL FIELD

The present invention relates to a copper alloy backing tube disposed on an inner circumferential side of a target material in a cylindrical sputtering target, and a method of manufacturing the copper alloy backing tube.

Priority is claimed on Japanese Patent Application No. 2016-079420, filed on Apr. 12, 2016, the content of which is incorporated herein by reference.

### BACKGROUND ART

As means for depositing a thin film such as a metal film or an oxide film, a sputtering method using a sputtering target is widely used.

Generally, a sputtering target has a structure in which a target material formed in accordance with the composition of a thin film to be deposited and a backing material holding this target material are bonded to each other via a bonding layer.

Examples of a bonding material constituting a bonding layer to be interposed between a target material and a backing material include an In alloy and a Sn—Pb alloy.

As the sputtering target described above, for example, a flat plate sputtering target and a cylindrical sputtering target are proposed.

The flat plate sputtering target has a structure in which a flat plate-shaped target material and a flat plate-shaped backing material (backing plate) are laminated.

In addition, the cylindrical sputtering target has a structure in which a cylindrical backing material (backing tube) is bonded to an inner circumferential side of a cylindrical target material via a bonding layer. In order to cope with deposition with respect to a large-sized substrate, a cylindrical target in which the length of a target material in an axial line direction is set to be relatively long, for example, 1,000 mm or longer is proposed.

In the flat plate sputtering target, the use efficiency of the target material ranges from approximately 20% to 30%, so that deposition cannot be efficiently performed.

In contrast, in the cylindrical sputtering target, its outer circumferential surface is a sputtering surface, and sputtering is performed while a target is rotated. Accordingly, compared to a case of using the flat plate sputtering target, the cylindrical sputtering target is suitable for continuous deposition, and since an erosion part spreads in a circumferential direction, the cylindrical sputtering target has an advantage that the use efficiency of the target material ranges from 60% to 80%, which is high.

Moreover, the cylindrical sputtering target is configured to be cooled from the inner circumferential side of the backing tube, and the erosion part spreads in the circumferential direction as described above. Therefore, a temperature rise in the target material can be minimized, and power density at the time of sputtering can be increased, so that a through-put of deposition can be further improved.

The backing tube described above is provided to hold a target material and to ensure mechanical strength. Moreover, the backing tube performs an operation such as electric power supply to the target material and cooling of the target material. Therefore, a backing tube is required to have excellent mechanical strength, electrical conductivity, and thermal conductivity. For example, a backing tube is constituted of stainless steel such as SUS304, copper or a copper alloy, and titanium.

Here, PTL 1 discloses a sputtering target including a backing tube constituted of copper or a copper alloy.

### CITATION LIST

### Patent Literature

[PTL 1] Japanese Unexamined Patent Application, First Publication No. 2015-212422

### SUMMARY OF INVENTION

### Technical Problem

Incidentally, a cylindrical sputtering target has a structure in which a target material is disposed on an outer circumferential side of a backing tube and both ends of the backing tube are supported by an attachment portion of a sputtering apparatus. In addition, a magnet or a water cooling mechanism is formed inside the backing tube.

Therefore, the own weight of the backing tube, the weight of the target material, and the weight of an internal structure of the backing tube are applied to an end portion of the backing tube, so that a significant bending stress load is locally applied.

In addition, when detaching a target material which has been consumed after use, the target material is drawn out by being heated in its entirety to melt a bonding layer.

Here, in a backing tube constituted of copper or a copper alloy in the related, deformation was caused due to a bending stress load applied to an end portion of the backing tube, so that it was difficult to detach a used target material, and there was concern that the backing tube cannot be repetitively used.

Since titanium backing tubes and stainless-steel backing tubes have high deformation resistance, the problem of bending deformation described above is unlikely to occur. However, titanium backing tubes and stainless-steel backing tubes have low thermal conductivity. Therefore, heat on a target material side cannot be sufficiently dissipated to an inner circumferential side of the backing tube when high-output sputtering is performed, thereby leading to a problem that a bonding layer melts or sputtering deposition becomes unstable.

This invention has been made in consideration of the foregoing circumstances, and an object thereof is to provide a copper alloy backing tube which minimizes deformation of the backing tube, is able to be repetitively used, has excellent heat radiation characteristics, and is able to cope with high-output sputtering deposition, and a method of manufacturing the copper alloy backing tube.

### Solution to Problem

In order to solve the problems, according to an aspect of the present invention, there is provided a copper alloy backing tube to be disposed on an inner circumferential side of a target material having a cylindrical shape in a cylindrical sputtering target. The copper alloy backing tube is formed of a copper alloy having a composition containing 0.10 mass % or more and 0.30 mass % or less of Co, 0.030 mass % or more and 0.10 mass % or less of P, 0.01 mass % or more and 0.50 mass % or less of Sn, 0.02 mass % or more and 0.10 mass % or less of Ni, and 0.01 mass % or more and 0.10 mass % or less of Zn. A copper balance containing inevitable impurities. A mass ratio [Co]/[P] of a Co content [Co] to a P content [P] is set to be within a range of 3.0 or higher and 6.0 or lower. A thermal conductivity is set to 250 W/(m·K) or higher. A micro-Vickers hardness after a heating treatment is performed in a condition of being held for one hour at 250° C. is 100 Hv or higher, and a decrease rate from a hardness before the heating treatment is set to 5% or less.

In the copper alloy backing tube according to the aspect of the present invention having such a configuration, since the copper alloy backing tube consists of a copper alloy having the composition described above, strength, electrical conductivity, thermal conductivity, and heat resistance can be improved by dispersing fine precipitates containing Co and P in a matrix. Specifically, since thermal conductivity is set to 250 W/(m·K) or higher, heat on the target material side can be efficiently dissipated to the inner circumferential side of the backing tube, and the copper alloy backing tube can cope with high-output sputtering deposition. In addition, since the micro-Vickers hardness after the heating treatment is performed in a condition of being held for one hour at 250° C. is set to 100 Hv or higher and the decrease rate from the hardness before the heating treatment is set to 5% or less, high-temperature strength and heat resistance become excellent, and bending deformation can be minimized even in a case where a bending stress load is applied at the time of sputtering. Thus, a used target material can be easily detached, and the copper alloy backing tube can be repetitively used.

Here, in the copper alloy backing tube according to the aspect of the present invention, it is preferable that an orientation of a (200) plane in a cross section orthogonal to an axial line is 50% or more.

In this case, deformation resistance with respect to a bending stress load increases, so that generation of bending deformation in an end portion of the copper alloy backing tube can be further minimized.

According to another aspect of the present invention, there is provided a method of manufacturing a copper alloy backing tube, which is a method of manufacturing the copper alloy backing tube described above including a melting and casting step of obtaining a copper alloy ingot having the composition, a hot extruding step of obtaining a raw tube by heating the copper alloy ingot at a temperature of 850° C. or higher and performing extrusion working, a fast rapid cooling step of rapidly cooling the raw tube after the hot extruding step, a cold drawing step of performing drawing working of the obtained raw tube in a condition of a cross-sectional shrinkage ratio ranging of 10% or more and 70% or less, and a heat treatment step of performing heat treatment of the raw tube after the cold drawing step in a condition where the raw tube is held for a period ranging of 1 hour or longer and 10 hours or shorter within a temperature range of 400° C. or higher and 600° C. or lower.

According to the method of manufacturing a copper alloy backing tube having this configuration, Co and P are dissolved in the hot extruding step in which a raw tube is obtained by heating the copper alloy ingot at a temperature of 850° C. or higher and performing extrusion working and in the succeeding fast rapid cooling step. Precipitates containing Co and P formed into solid solutions can be dispersed in the heat treatment step of performing heat treatment of a raw tube after the cold drawing step. Therefore, strength and heat resistance can be improved without causing thermal conductivity and electrical conductivity to significantly deteriorate.

Specifically, thermal conductivity of a copper alloy backing tube can be set to 250 W/(m·K) or higher.

Moreover, a micro-Vickers hardness after a heating treatment is performed in a condition of being held for one hour at 250° C. can be set to 100 Hv or higher, and the decrease rate from a hardness before the heating treatment can be set to 5% or less.

### Advantageous Effects of Invention

As described above, according to the present invention, it is possible to provide a copper alloy backing tube which minimizes deformation of the backing tube, is able to be repetitively used, has excellent heat radiation characteristics, and is able to cope with high-output sputtering deposition, and a method of manufacturing the copper alloy backing tube.

### BRIEF DESCRIPTION OF DRAWINGS

FIG. 1 is a schematic view illustrating a cylindrical sputtering target including a copper alloy backing tube according to an embodiment of the present invention. FIG. 1(a) is a cross-section view orthogonal to an axial line O direction, and FIG. 1(b) is a cross-sectional view taken along an axial line O.

FIG. 2 is a view illustrating a site of collecting a sample for measuring a crystal orientation.

FIG. 3 is a flow chart of a method of manufacturing a copper alloy backing tube according to the embodiment of the present invention.

FIG. 4 is a view illustrating a cold drawing step.

FIG. 5 is a view illustrating a method of measuring a maximum deformation amount of a backing tube.

### DESCRIPTION OF EMBODIMENT

Hereinafter, a cylindrical sputtering target including a copper alloy backing tube as an embodiment of the present invention will be described with reference to the accompanying drawings.

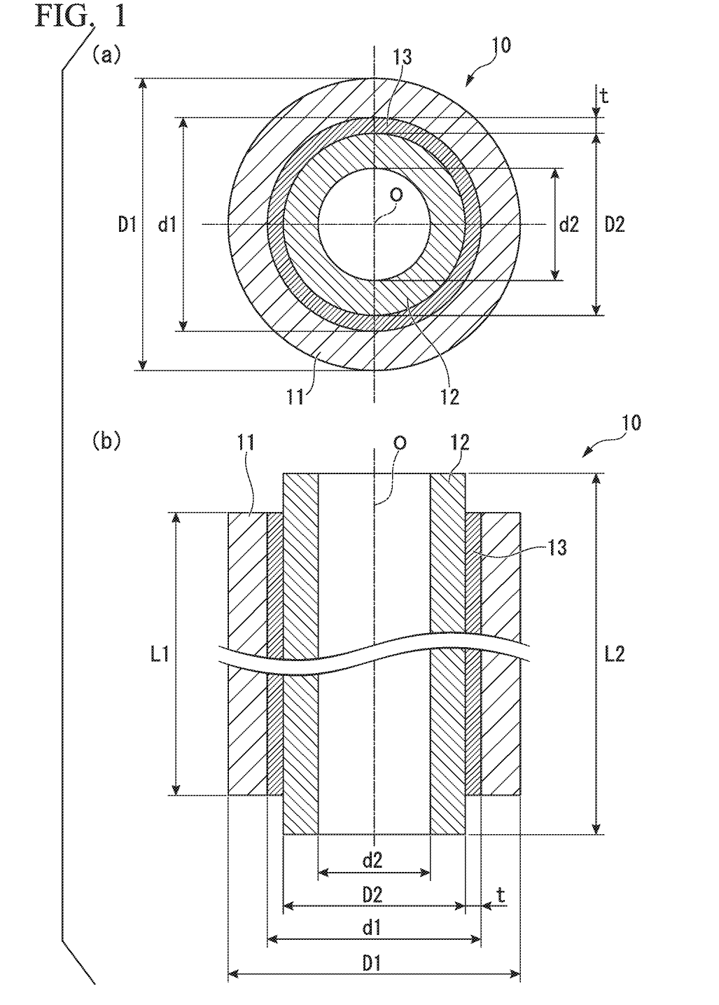

As illustrated in FIG. 1, a cylindrical sputtering target 10 in the present embodiment includes a target material 11 having a cylindrical shape extending along an axial line O, and a copper alloy backing tube 12 of the present embodiment inserted on an inner circumferential side of the target material 11.

Then, the target material 11 and the copper alloy backing tube 12 are bonded to each other via a bonding layer 13.

The target material 11 is composed in accordance with the composition of a thin film to be deposited and is constituted of various kinds of metal, oxide, and the like.

In addition, for example, an outer diameter D1 of the target material 11 is D2+10 mm≤D1≤D2+50 mm with respect to an outer diameter D2 of a backing tube, an inner diameter d1 is D2+1 mm≤d1≤D2+6 mm with respect to the outer diameter D2 of the backing tube, and a length L1 in an axial line O direction is set to 500 mm≤L1≤5,000 mm, approximately.

The bonding layer 13 interposed between the target material 11 and the copper alloy backing tube 12 is formed when the target material 11 and the copper alloy backing tube 12 are bonded to each other using a bonding material.

For example, the bonding material constituting the bonding layer 13 is constituted of a low melting metal such as In or an In alloy. In addition, a thickness t of the bonding layer 13 is set to be within a range of 0.5 mm≤t≤3 mm.

Then, the copper alloy backing tube 12 of the present embodiment is provided to hold the target material 11 and to ensure mechanical strength. Moreover, the copper alloy backing tube 12 performs an operation such as electric power supply to the target material 11 and cooling of the target material 11.

Here, the copper alloy backing tube 12 of the present embodiment consists of a copper alloy having a composition containing 0.10 mass % or more and 0.30 mass % or less of Co, 0.030 mass % or more and 0.10 mass % or less of P, 0.01 mass % or more and 0.50 mass % or less of Sn, 0.02 mass % or more and 0.10 mass % or less of Ni, and 0.01 mass % or more and 0.10 mass % or less of Zn. A copper balance containing inevitable impurities. A mass ratio [Co]/[P] of a Co content [Co] to a P content [P] is set to be within a range of 3.0 or higher and 6.0 or lower.

The copper alloy described above may further contain one or more of 0.002 mass % or more and 0.2 mass % or less of Mg, 0.003 mass % or more and 0.5 mass % or less of Ag, 0.002 mass % or more and 0.3 mass % or less of Al, 0.002 mass % or more and 0.2 mass % or less of Si, 0.002 mass % or more and 0.3 mass % or less of Cr, and 0.001 mass % or more and 0.1 mass % or less of Zr.

In the copper alloy backing tube 12 of the present embodiment, a thermal conductivity is set to 250 W/(m·K) or higher. The upper limit for the thermal conductivity of the copper alloy backing tube 12 is not limited and is realistically 340 W/(m·K) or lower.

In addition, in the copper alloy backing tube 12 of the present embodiment, a micro-Vickers hardness after a heating treatment is performed in a condition of being held for one hour at 250° C. is 100 Hv or higher, and a decrease rate from the hardness before the heating treatment is set to 5% or less. The upper limit for the micro-Vickers hardness after heating treatment is not limited and is realistically 200 Hv or lower.

Moreover, in the copper alloy backing tube 12 of the present embodiment, a crystal orientation of a (200) plane in a cross section orthogonal to the axial line O is set to 50% or more. The upper limit for the crystal orientation of the (200) plane in a cross section orthogonal to the axial line O is not limited and may be 80% or less.

In addition, in the copper alloy backing tube 12 of the present embodiment, it is preferable that electrical conductivity is 60% of IACS or higher.

In regard to the size of the copper alloy backing tube 12 of the present embodiment, the outer diameter D2 is 140 mm≤D2≤143 mm in a state before mechanical working after a drawing step. An inner diameter d2 maintains the dimensions after drawing. A length L2 in the axial line O direction after drawing becomes 7,000 mm or shorter. In addition, after drawing, heat treatment is performed, and the copper alloy backing tube 12 is finished as a backing tube through cutting and mechanical working.

Here, a reason for restricting the composition, the thermal conductivity, the hardness, and the crystal orientation of the copper alloy backing tube 12 as described above will be described.

(Co: 0.10 Mass % or More and 0.30 Mass % or Less)

Co is co-doped with P, thereby forming precipitates in a heat treatment step and having an operational effect of improving hardness and heat resistance. In addition, Co formed into solid solutions in a matrix is precipitated, so that thermal conductivity and electrical conductivity are improved. Here, if the Co content is less than 0.10 mass %, precipitates containing Co and P cannot be sufficiently formed, and an effect of improving hardness becomes insufficient. On the other hand, if the Co content exceeds 0.30 mass %, excessive Co is formed into solid solutions, and thermal conductivity and electrical conductivity deteriorate.

Consequently, in the present embodiment, the Co content is restricted to a range from 0.10 mass % or more and 0.30 mass % or less. In a case where hardness is to be further improved, the lower limit for the Co content is preferably 0.13 mass % or more and is more preferably 0.15 mass % or more. In addition, in order to reliably minimize deterioration of thermal conductivity and electrical conductivity, the upper limit for the Co content is preferably 0.28 mass % or less and is more preferably 0.25 mass % or less.

(P: 0.030 Mass % or More and 0.10 Mass % or Less)

P is co-doped with Co, thereby forming precipitates in the heat treatment step and having an operational effect of improving hardness and heat resistance. In addition, P formed into solid solutions in a matrix is precipitated, so that thermal conductivity and electrical conductivity are improved. Here, if the P content is less than 0.030 mass %, precipitates containing Co and P cannot be sufficiently formed, and an effect of improving hardness becomes insufficient. On the other hand, if the P content exceeds 0.10 mass %, excessive P is formed into solid solutions, and thermal conductivity and electrical conductivity deteriorate, and there are cases where a crack is caused in a hot extruding step.

Consequently, in the present embodiment, the P content is restricted to a range of 0.030 mass % or more and 0.10 mass % or less. In a case where hardness is to be further improved, the lower limit for the P content is preferably 0.045 mass % or more and is more preferably 0.050 mass % or more. In addition, in order to reliably minimize deterioration of thermal conductivity and electrical conductivity, the upper limit for the P content is preferably 0.080 mass % or less and is more preferably 0.065 mass % or less.

([Co]/[P])

As described above, Co and P are co-doped, so that it is possible to form fine precipitates such as Co₂P, to enhance hardness, to further improve heat resistance, and to improve thermal conductivity. Here, in a case where the mass ratio [Co]/[P] of the Co content [Co] to the P content [P] is lower than 3.0 or exceeds 6.0, any of the elements is formed into solid solutions in the matrix, so that thermal conductivity and electrical conductivity deteriorate.

Consequently, in the present embodiment, the mass ratio [Co]/[P] of the Co content [Co] to the P content [P] is set within a range of 3.0 or higher and 6.0 or lower. The lower limit for the mass ratio [Co]/[P] is preferably 3.3 or higher and is more preferably 3.5 or higher. In addition, the upper limit for the mass ratio [Co]/[P] is preferably 4.5 or lower and is more preferably 4.0 or lower.

(Sn: 0.01 Mass % or More and 0.50 Mass % or Less)

Sn is formed into solid solutions in a matrix, thereby improving hardness, improving heat resistance, and having an operational effect of minimizing deterioration of hardness even in a case of being held at a high temperature. Here, in a case where a Sn content is less than 0.01 mass %, there is concern that an effect of improving heat resistance cannot be sufficiently achieved. On the other hand, if the Sn content exceeds 0.5 mass %, deformation resistance at the time of hot working increases, and workability deteriorates.

Consequently, in the present embodiment, the Sn content is restricted to a range from 0.01 mass % or more and 0.50 mass % or less. In a case where heat resistance is to be further improved, the lower limit for the Sn content is preferably 0.04 mass % or more and is more preferably 0.06 mass % or more. In addition, in order to sufficiently ensure hot workability, the upper limit for the Sn content is preferably 0.20 mass % or less and is more preferably 0.15 mass % or less.

(Ni: 0.02 Mass % or More and 0.10 Mass % or Less)

Ni has an effect of promoting bonding between Co and P and is effective in improving hardness. Here, if a Ni content is less than 0.02 mass %, bonding between Co and P cannot be sufficiently promoted, and there is concern that the effect of improving hardness cannot be achieved. On the other hand, if the Ni content exceeds 0.10 mass %, excessive Ni is formed into solid solutions in a matrix, and there is concern that thermal conductivity and electrical conductivity may deteriorate.

Consequently, in the present embodiment, the Ni content is restricted to a range from 0.02 mass % or more and 0.10 mass % or less. In order to reliably promote bonding between Co and P, the lower limit for the Ni content is preferably 0.03 mass % or more. In addition, in order to further minimize deterioration of thermal conductivity and electrical conductivity, the upper limit for the Ni content is preferably 0.08 mass % or less and is more preferably 0.06 mass % or less.

(Zn: 0.01 Mass % or More and 0.10 Mass % or Less)

Zn is formed into solid solutions in a matrix, thereby having an operational effect of improving hardness and improving heat resistance. In addition, Zn has an operational effect of improving solder wettability. Here, if a Zn content is less than 0.01 mass %, there is concern that hardness and heat resistance cannot be sufficiently improved. On the other hand, if the Zn content exceeds 0.10 mass %, there is concern that thermal conductivity and electrical conductivity may deteriorate.

Consequently, in the present embodiment, the Zn content is restricted to a range from 0.01 mass % or more and 0.10 mass % or less. In order to reliably improve hardness and heat resistance, the lower limit for the Zn content is preferably 0.03 mass % or more. In addition, in order to further minimize deterioration of thermal conductivity and electrical conductivity, the upper limit for the Zn content is preferably 0.08 mass % or less.

As described above, the copper alloy backing tube 12 of the present embodiment may suitably contain elements such as Mg, Ag, Al, Si, Cr, and Zr other than the added elements described above.

Mg, Ag, Al, and Si are elements having an operational effect of further improving hardness due to hardening of solid solutions, and Cr and Zr are elements having the same operational effect due to hardening of precipitates. In addition, Ag has an operational effect of further improving heat resistance. In order to improve hardness without causing thermal conductivity and electrical conductivity to significantly deteriorate, it is preferable that each of the added amounts of these elements is set within the range described above.

(Thermal Conductivity)

Radiant heat from plasma generated during sputtering is transferred to the inside from the surface of the target material 11, passes through the copper alloy backing tube 12, and is removed by cooling water flowing on the inner circumferential side of the copper alloy backing tube 12. Therefore, in a case where the thermal conductivity of the copper alloy backing tube 12 is low, the temperature of the target material 11 rises due to an insufficient heat removal effect, and there is concern that the bonding layer 13 interposed between the target material 11 and the copper alloy backing tube 12 may melt. Therefore, it is preferable for the copper alloy backing tube 12 to have higher thermal conductivity. Specifically, the thermal conductivity is favorably 250 W/(m·K) or higher.

(Hardness)

When the target material 11 is subjected to bonding and when the used target material 11 after sputtering ends is detached, there is a need to continue heating for a certain period of time and to maintain a bonding layer in a melted state in any case above. Therefore, the copper alloy backing tube 12 needs to have heat resistance such that strength does not deteriorate even if the copper alloy backing tube 12 is heated. Particularly, the copper alloy backing tube 12 needs to have characteristics preventing deterioration of hardness even if the copper alloy backing tube 12 is held in a repetitive high-temperature state. In order to repetitively use the copper alloy backing tube 12, it is preferable that the micro-Vickers hardness is 100 Hv or higher even after heating. In addition, it is preferable that deterioration of hardness after heating is 5% or less than that of hardness before heating.

Therefore, in the present embodiment, the micro-Vickers hardness after heating treatment is performed in a condition of being held for one hour at 250° C. is 100 Hv or higher, and the decrease rate from hardness before the heating treatment is set to 5% or less. In addition, the decrease rate from hardness before the heating treatment is more preferably 1% or less.

(Crystal Orientation)

The cylindrical sputtering target 10 has a structure in which both ends of the copper alloy backing tube 12 are supported by attachment portions of a sputtering apparatus, so that a load is concentrated in the end portions of the copper alloy backing tube 12 and a significant bending stress load is locally applied.

Here, the crystal orientation is adjusted such that the crystal orientation of the (200) plane in a cross section orthogonal to the axial line O becomes 50% or more, so that deformation resistance with respect to bending increases and bending deformation is unlikely to occur. Therefore, in the present embodiment, the crystal orientation of the copper alloy backing tube 12 is adjusted as described above.

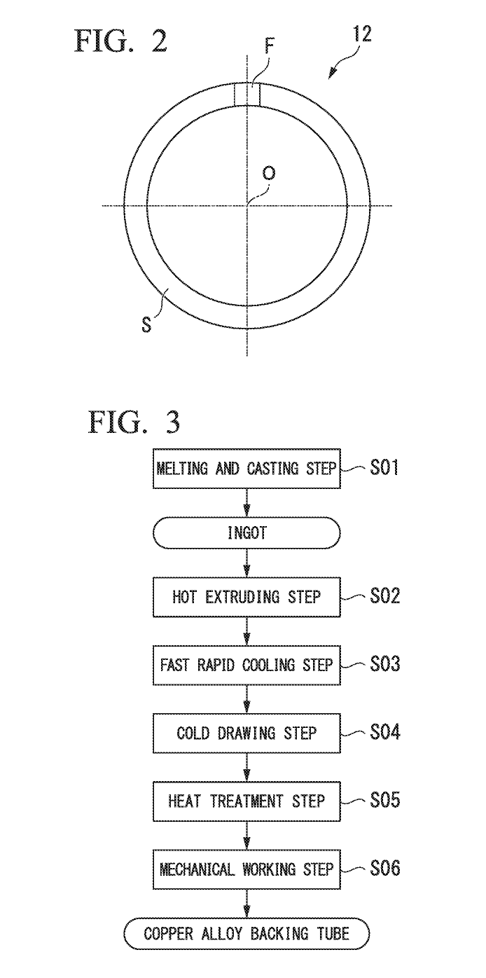

Here, the crystal orientation of the (200) plane in a cross section orthogonal to the axial line O is obtained as follows. As illustrated in FIG. 2, a measurement sample F is collected from a cross section S orthogonal to the axial line O. The crystal orientation of the (200) plane can be obtained by an expression having the total of values respectively obtained by dividing the peak strengths of a (111) plane, the (200) plane, a (220) plane, and a (311) plane measured through powder X-ray diffractometry by the standard strength of a diffraction peak in each of the crystal planes disclosed in the JCPDS card (DB card number 00-04-0836), as the denominator, and the value obtained by dividing the peak strength of the (200) plane obtained through the powder X-ray diffractometry by the standard strength of a peak in the (200) plane disclosed in the JCPDS card (DB card number 00-04-0836), as the numerator.

That is, when the measured peak strengths of the (111) plane, the (200) plane, the (220) plane, and the (311) plane are I₁₁₁, I₂₀₀, I₂₂₀, and I₃₁₁, and the standard strengths of the crystal planes disclosed in the JCPDS card are I_{S111}, I_{S200}, I_{S220}, and I_{S311}, the orientation (%) of the (220) plane is obtained by the following Expression.

$$Orientation of ( 200 ) plane ( \% ) = 100 \times \frac{{I}_{200} \text{/} {I}_{S 200}}{( {I}_{111} \text{/} {I}_{S 111} ) + ( {I}_{200} \text{/} {I}_{S 200} ) + ( {I}_{220} \text{/} {I}_{S 220} ) + ( {I}_{311} \text{/} {I}_{S 311} )}$$

Next, a method of manufacturing the copper alloy backing tube 12 of the present embodiment described above will be described.

FIG. 3 illustrates a flow chart of the method of manufacturing the copper alloy backing tube 12 of the present embodiment.

First, a melting raw material is weighed to have the composition described above, and the melting raw material is subjected to melting and casting. Then, a copper alloy ingot having a columnar shape is manufactured (melting and casting step S01).

Next, an obtained copper alloy ingot is heated for 2 to 10 minutes at 850° C. or higher. Thereafter, a cylindrical raw tube is manufactured through hot extrusion working (hot extruding step S02). In this hot extruding step S02, a cross-sectional shrinkage ratio is not particularly set but is preferably 90% or more. A heating temperature in the hot extruding step S02 is preferably 1,000° C. or lower but is not limited thereto.

Here, “the cross-sectional shrinkage ratio” is obtained by the cross-sectional shrinkage ratio (%)=100×(A₀−A₁)/A₀, when a cross section before working is A₀ and a cross section after working is A₁.

Next, after the hot extruding step S02, water cooling is immediately performed (fast rapid cooling step S03). Accordingly, Co and P are formed into solid solutions in the matrix.

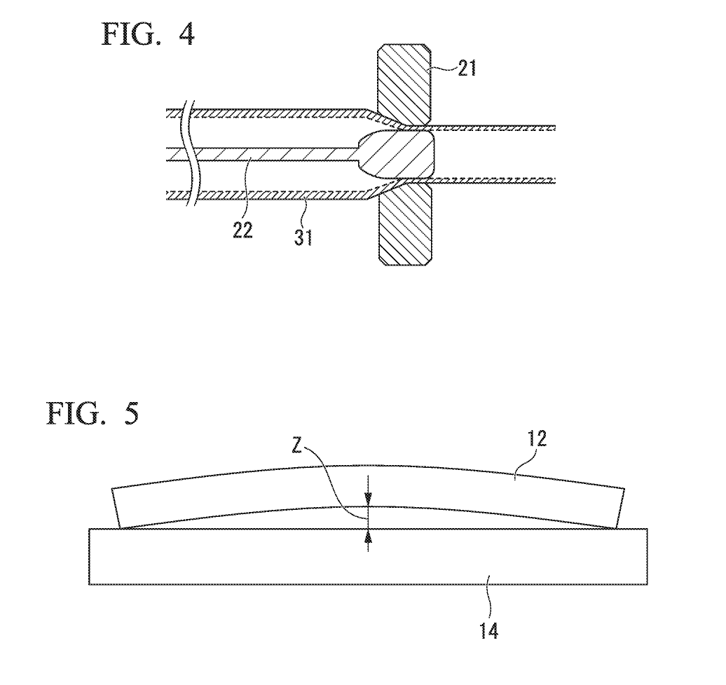

Next, a raw tube manufactured in the hot extruding step S02 becomes a raw tube for a backing tube having a predetermined outer diameter and a predetermined inner diameter through cold drawing working (cold drawing step S04). In this cold drawing step S04, first, osculating working is performed such that a tip portion of the raw tube passes through between an outer diameter die (die 21) and an inner diameter die (plug 22). Thereafter, as illustrated in FIG. 4, drawing working is performed by causing an osculation portion of a raw tube 31 to pass through between the die 21 and the plug 22 and drawing the osculation portion. It is desirable that the cross-sectional shrinkage ratio in this cold drawing step S04 ranges from 10% to 70%. In addition, drawing may be performed in one step or may be performed through many stages.

Next, a raw tube for a backing tube after the cold drawing step S04 is subjected to heat treatment in a condition of being held for a period ranging of 1 hour or longer and 10 hours or shorter within a temperature range of 400° C. or higher and 600° C. or lower (heat treatment step S05). In this heat treatment step S05, Co and P formed into solid solutions are precipitated, so that hardness of the copper alloy backing tube 12 is improved and heat resistance is applied at the same time.

Moreover, anisotropy is manifested in the crystal orientation of the copper alloy backing tube 12 to have an effect of preventing deformation in the end portion of the copper alloy backing tube 12 or in the vicinity thereof.

Here, if the heat treatment temperature is lower than 400° C., Co and P formed into solid solutions cannot be sufficiently precipitated, so that hardness and heat resistance cannot be improved. In addition, thermal conductivity and electrical conductivity decrease. On the other hand, if the heat treatment temperature exceeds 600° C., precipitates are formed into solid solutions again or are coarsened, so that sufficient hardness cannot be achieved.

In a case where the heat treatment time is less than one hour, Co and P formed into solid solutions cannot be sufficiently precipitated, so that hardness and heat resistance cannot be improved. On the other hand, even if the heat treatment time exceeds ten hours, the effect is not further improved.

Consequently, in the present embodiment, the heat treatment temperature is set to range of 400° C. or higher and 600° C. or lower, and the heat treatment time is set to range of 1 hour or longer and 10 hours or shorter. The lower limit for the heat treatment temperature is preferably 450° C. or higher, and the upper limit for the heat treatment temperature is preferably 500° C. or lower. The lower limit for the heat treatment time is preferably two hours or longer, and the upper limit for the heat treatment time is preferably eight hours or shorter. However, the embodiment is not limited thereto.

Then, mechanical working is performed after the heat treatment step S05, so that the size and the shape of the copper alloy backing tube 12 are adjusted (mechanical working step S06).

According to the steps described above, the copper alloy backing tube 12 of the present embodiment is manufactured.

According to the copper alloy backing tube 12 of the present embodiment having the configuration described above, since the copper alloy backing tube consists of a copper alloy having the composition described above, strength and heat resistance can be improved without causing thermal conductivity and electrical conductivity to significantly deteriorate, by dispersing fine precipitates containing Co and P.

In addition, since the thermal conductivity of the copper alloy backing tube 12 is set to 250 W/(m·K) or higher, heat on the surface of the target material 11 can be efficiently dissipated to the inner circumferential side of the copper alloy backing tube 12, and the copper alloy backing tube 12 can cope with high-output sputtering deposition.

Moreover, in the copper alloy backing tube 12 of the present embodiment, since the micro-Vickers hardness after heating treatment is performed in a condition of being held for one hour at 250° C. is set to 100 Hv or higher and the decrease rate from hardness before heating treatment is set to 5% or less, high-temperature strength and heat resistance become excellent, and bending deformation can be minimized even in a case where a bending stress load is applied to the end portion of the copper alloy backing tube 12 at the time of sputtering. Thus, a used target material 11 can be easily detached, and the copper alloy backing tube 12 can be repetitively used.

Moreover, in the copper alloy backing tube 12 of the present embodiment, since the orientation of the (200) plane in a cross section orthogonal to the axial line O is set to 50% or more, deformation resistance with respect to bending increases, so that generation of bending deformation in the end portion of the copper alloy backing tube 12 can be further minimized.

According to the method of manufacturing the copper alloy backing tube 12 of the present embodiment, Co and P are dissolved in the hot extruding step S02 in which a raw tube is obtained by heating a copper alloy ingot for 2 to 10 minutes at 850° C. or higher and performing extrusion working and in the succeeding fast rapid cooling step S03. Precipitates containing Co and P formed into solid solutions can be precipitated and dispersed in the heat treatment step S05 after the cold drawing step S04. Therefore, strength can be improved without causing thermal conductivity and electrical conductivity to significantly deteriorate.

In addition, the thermal conductivity of the copper alloy backing tube 12 can be set to 250 W/(m·K) or higher.

Moreover, hardness and heat resistance of the copper alloy backing tube 12 can be improved, the micro-Vickers hardness after heating treatment is performed in a condition of being held for one hour at 250° C. can be set to 100 Hv or higher, and the decrease rate from hardness before heating treatment can be set to 5% or less.

Hereinabove, the embodiment of the present invention has been described. However, the present invention is not limited thereto and can be suitably changed in a range not departing from the technical idea of the invention.

### EXAMPLES

Hereinafter, the results of confirmation tests performed to confirm the operational effects of the copper alloy backing tube according to the present invention will be described.

Backing tubes were manufactured in accordance with the flow chart illustrated in FIG. 3. Ingots having the composition shown in Table 1 were manufactured by performing melting and casting using a high frequency melting furnace. As the size of the ingots, the diameter was 360 mm and the length was 640 mm.

Next, in the conditions shown in Table 2, backing tubes were manufactured through the hot extruding step including solution treatment, the cold drawing step, and the heat treatment step at the end.

A part of each of the backing tubes was cut in round slices to collect an orientation measurement sample illustrated in FIG. 2, and a thermal conductivity measurement sample and a hardness measurement sample were collected from the balance. As the dimensions of the backing tubes after drawing working, the outer diameter was ϕ140 to 142 mm, and the inner diameter was ϕ125 mm in all of the backing tubes. In addition, after heat treatment, the inner diameter was not subjected to working, but the outer diameter and the length were subjected to mechanical working to be ϕ135 mm and 1,950 mm, respectively.

Comparative Example 20 was a raw tube formed of commercially available oxygen-free copper (C1020).

<Measurement of Thermal Conductivity>

Thermal conductivity was measured by a laser flash method. The measured sample had dimensions of the diameter: 10 mm and the thickness: 1 mm. In addition, the measurement was performed at 25° C.

<Evaluation of Heat Resistance>

In the sample collected for the evaluation of heat resistance, a measurement surface was polished, and its hardness was measured with a micro Vickers hardness meter. Next, as shown in Table 3, heating treatment was performed in a condition of being held for one hour at 250° C., and hardness was measured again. When the hardness before heating treatment was H₀ and the hardness after heating treatment was H₁, heat resistance was evaluated based on the decrease rate (%) of the hardness defined by the following expression.

Decrease rate (%) of hardness=100×(H₀−H₁)/H₀

<Evaluation of Crystal Orientation>

As in FIG. 2, a sample for measuring the crystal orientation was collected, and a cross section orthogonal to the axial line was polished. The diffraction peak strengths from the (111) plane, the (200) plane, the (220) plane, and the (311) plane were measured using a powder X-ray diffraction apparatus. Then, the crystal orientation of the (200) plane was calculated by the expression described in the embodiment.

<Evaluation of Maximum Deformation Amount after Sputtering Test>

In order to confirm the performance of the copper alloy backing tube, a sputtering test was performed. In the sputtering test, two cylindrical target materials which are made of oxygen-free copper and have the inner diameter of ϕ137 mm, the outer diameter of ϕ180 mm, and the length of 725 mm were prepared separately. The target material was bonded to a copper alloy backing tube using In solder. At this time, the clearance between the targets was set to approximately 1 mm. After the obtained cylindrical sputtering target was attached to a sputtering apparatus, evacuation was performed, and the sputtering test was performed in the following conditions.

Vacuum pressure to reach: <1×10⁻⁴ Pa

Sputtering gas: Ar

Sputtering gas pressure: 0.5 Pa

Sputtering output: direct current, 25 kW

Rotational frequency of target: 10 rpm

Sputtering period: 3 hours continuously

After sputtering, the target materials were cooled for one hour, and the cylindrical sputtering target was taken out from the sputtering apparatus. Thereafter, the cylindrical sputtering target was heated to approximately 250° C. such that the solder was melted, and the target material was detached from the copper alloy backing tube by pulling.

Thereafter, solder remaining on the bonding surface of the copper alloy backing tube was wiped, and a maximum deformation amount Z of the copper alloy backing tube was measured.

After the maximum deformation amount Z was measured, the target material was bonded to the copper alloy backing tube again and was subjected to second sputtering in similar conditions. After the second sputtering, the maximum deformation amount Z of the copper alloy backing tube was measured by a method similar to that of the first sputtering.

After the maximum deformation amount Z was measured, the target material was bonded to the copper alloy backing tube again and was subjected to third sputtering in similar conditions. After the third sputtering, the maximum deformation amount Z of the copper alloy backing tube was measured by a similar method. As illustrated in FIG. 5, as the maximum deformation amount Z, the copper alloy backing tube 12 was placed on a surface plate 14, and the clearance between the surface plate 14 and the copper alloy backing tube 12 was measured by using a clearance gauge.

TABLE 1

| | Alloy | Alloy composition (wt %) | | | | | | |
|---|---|---|---|---|---|---|---|---|
| | No. | Co | P | Co/P ratio | Sn | Ni | Zn | Cu |
| Examples of | 1 | 0.10 | 0.030 | 3.3 | 0.01 | 0.02 | 0.01 | Remained |
| the present | 2 | 0.15 | 0.035 | 4.3 | 0.1 | 0.05 | 0.05 | Remained |
| invention | 3 | 0.15 | 0.035 | 4.3 | 0.5 | 0.10 | 0.10 | Remained |
| | 4 | 0.20 | 0.040 | 5.0 | 0.1 | 0.05 | 0.05 | Remained |
| | 5 | 0.20 | 0.040 | 5.0 | 0.3 | 0.05 | 0.05 | Remained |
| | 6 | 0.20 | 0.040 | 5.0 | 0.5 | 0.05 | 0.05 | Remained |
| | 7 | 0.20 | 0.060 | 3.3 | 0.1 | 0.05 | 0.05 | Remained |
| | 8 | 0.30 | 0.050 | 6.0 | 0.1 | 0.05 | 0.05 | Remained |
| | 9 | 0.30 | 0.10 | 3.0 | 0.1 | 0.05 | 0.05 | Remained |
| | 10 | 0.30 | 0.050 | 6.0 | 0.1 | 0.10 | 0.05 | Remained |
| Comparative | 11 | 0.05 | 0.030 | 1.7 | 0.01 | 0.02 | 0.01 | Remained |
| Examples | 12 | 0.40 | 0.030 | 13.3 | 0.01 | 0.02 | 0.01 | Remained |
| | 13 | 0.15 | 0.010 | 15.0 | 0.1 | 0.05 | 0.05 | Remained |
| | 14 | 0.15 | 0.15 | 1.0 | 0.1 | 0.05 | 0.05 | Remained |
| | 15 | 0.20 | 0.040 | 5.0 | 0.005 | 0.05 | 0.05 | Remained |
| | 16 | 0.20 | 0.040 | 5.0 | 0.8 | 0.05 | 0.05 | Remained |
| | 17 | 0.20 | 0.040 | 5.0 | 0.1 | 0.005 | 0.05 | Remained |
| | 18 | 0.20 | 0.040 | 5.0 | 0.1 | 0.2 | 0.05 | Remained |
| | 19 | 0.30 | 0.10 | 3.0 | 0.1 | 0.05 | 0.005 | Remained |
| | 20 | 0.30 | 0.10 | 3.0 | 0.1 | 0.05 | 0.2 | Remained |

| | | |
|---|---|---|
| 21 | Oxygen-free copper raw tube (JIS No. C1020 1/4II material) | More than 99.96% |

TABLE 2

| | | | Manufacturing conditions | | | | | |
|---|---|---|---|---|---|---|---|---|
| | | | Extrusion step | | | | | |
| | | | | | | Dimensions after | | Cross-sectional |
| | | | Heating | Cooling start | | extrusion | | shrinkage ratio |
| | | | temperature ⁽*⁾ | temperature | | Outer | Inner | after extrusion |
| | Alloy | Process | before extrusion | after extrusion | Cooling | diameter | diameter | from ingot |
| | No | No | (° C.) | (° C.) | method | (ϕmm) | (ϕmm) | (%) |
| Examples of | 1 | 1-1 | 880° C. | 850° C. | Water cooling | 171 | 132 | 91 |
| the present | 2 | 2-1 | 880° C. | 850° C. | Water cooling | 171 | 132 | 91 |
| invention | 3 | 3-1 | 880° C. | 850° C. | Water cooling | 171 | 132 | 91 |
| | 4 | 4-1 | 900° C. | 870° C. | Water cooling | 150 | 132 | 96 |
| | 5 | 5-1 | 900° C. | 870° C. | Waler cooling | 150 | 132 | 96 |
| | 6 | 6-1 | 900° C. | 870° C. | Water cooling | 150 | 132 | 96 |
| | 7 | 7-1 | 900° C. | 870° C. | Water cooling | 150 | 132 | 96 |
| | | 7-2 | 900° C. | 870° C. | Water cooling | 150 | 132 | 96 |
| | | 7-3 | 900° C. | 870° C. | Water cooling | 150 | 132 | 96 |
| | 8 | 8-1 | 920° C. | 890° C. | Water cooling | 150 | 132 | 96 |
| | 9 | 9-1 | 920° C. | 890° C. | Water cooling | 150 | 132 | 96 |
| | 10 | 10-1 | 920° C. | 890° C. | Water cooling | 150 | 132 | 96 |
| Comparative | 4 | 4-2 | 900° C. | 870° C. | Water cooling | 150 | 132 | 96 |
| Examples | 11 | 11-1 | 900° C. | 870° C. | Water cooling | 185 | 132 | 87 |
| | 12 | 12-1 | 900° C. | 870° C. | Water cooling | 147 | 132 | 97 |
| | 13 | 13-1 | 900° C. | — | Radiant cooling | 150 | 132 | 96 |
| | 14 | | 900° C. | 870° C. | Water cooling | A crack was caused in extrusion step. | | |
| | | | | | | Succeeding tests were not performed. | | |
| | 15 | 15-1 | 840° C. | 800° C. | Water cooling | 147 | 132 | 96 |
| | 16 | 16-1 | 840° C. | 800° C. | Water cooling | 147 | 132 | 96 |
| | 17 | 17-1 | 960° C. | 920° C. | Water cooling | 147 | 132 | 96 |
| | 18 | 18-1 | 960° C. | 920° C. | Water cooling | 147 | 132 | 96 |
| | 19 | 19-1 | 900° C. | 870° C. | Water cooling | 147 | 132 | 96 |
| | 20 | 20-1 | 900° C. | 870° C. | Water cooling | 147 | 132 | 96 |
| | 21 | | | | | | | |

| | | | Manufacturing conditions | | | |
|---|---|---|---|---|---|---|
| | | | Drawing step | | | |
| | | | Dimensions after drawing | | | |
| | | | | | Cross-sectional | |
| | | | | | shrinkage ratio | Heat |
| | | | Outer | Inner | until drawing from | treatment step |
| | Alloy | Process | diameter | diameter | extruded raw tube ends | Heat |
| | No | No | (ϕmm) | (ϕmm) | (%) | treatment conditions |
| Examples of | 1 | 1-1 | 140 | 125 | 66 | 420° C. × 3 hours |
| the present | 2 | 2-1 | 140 | 125 | 66 | 420° C. × 5 hours |
| invention | 3 | 3-1 | 140 | 125 | 66 | 420° C. × 10 hours |
| | 4 | 4-1 | 140 | 125 | 23 | 470° C. × 3 hours |
| | 5 | 5-1 | 140 | 125 | 23 | 470° C. × 3 hours |
| | 6 | 6-1 | 140 | 125 | 23 | 500° C. × 3 hours |
| | 7 | 7-1 | 140 | 125 | 23 | 500° C. × 3 hours |
| | | 7-2 | 142 | 125 | 12 | 500° C. × 3 hours |
| | | 7-3 | 140 | 125 | 23 | 580° C. × 3 hours |
| | 8 | 8-1 | 140 | 125 | 23 | 500° C. × 3 hours |
| | 9 | 9-1 | 140 | 125 | 23 | 500° C. × 3 hours |
| | 10 | 10-1 | 140 | 125 | 23 | 500° C. × 3 hours |
| Comparative | 4 | 4-2 | 140 | 125 | 23 | 470° C. × 0.5 hours |
| Examples | 11 | 11-1 | 140 | 125 | 76 | 420° C. × 3 hours |
| | 12 | 12-1 | 140 | 125 | 8 | 580° C. × 3 hours |
| | 13 | 13-1 | 140 | 125 | 23 | 470° C. × 3 hours |

| 14 | A crack was caused in extrusion step. | | | | |
|---|---|---|---|---|---|
| | Succeeding tests were not performed. | | | | |
| 15 | 15-1 | 140 | 125 | 8 | 470° C. × 3 hours |
| 16 | 16-1 | 140 | 125 | 8 | 470° C. × 3 hours |
| 17 | 17-1 | 140 | 125 | 8 | 470° C. × 3 hours |
| 18 | 18-1 | 140 | 125 | 8 | 470° C. × 3 hours |
| 19 | 19-1 | 140 | 125 | 8 | 470° C. × 3 hours |
| 20 | 20-1 | 140 | 125 | 8 | 470° C. × 3 hours |
| 21 | | | | | |

⁽*⁾ The heating time ranges from 2 to 10 minutes (using a medium frequency heating furnace).

TABLE 3

| | | | | Evaluation of heat resistance | | | |
|---|---|---|---|---|---|---|---|
| | | | | | hardness | hardness | IIardness |
| | | | Thermal | | before | after | decrease |
| | Alloy | Process | conductivity | Heating | heating | heating | rate ⁽*⁾ (%) |
| | No | No | (W/m · K) | conditions | H₀ (mHv) | H₁ (mHv) | (II₀ − II₁)/II₀ |
| Examples of | 1 | 1-1 | 296 | 250° C. × 1 hour | 105 | 107 | −1.9% |
| the present | 2 | 2-1 | 284 | | 110 | 111 | −0.9% |
| invention | 3 | 3-1 | 281 | | 118 | 121 | −2.5% |
| | 4 | 4-1 | 279 | | 124 | 128 | −3.2% |
| | 5 | 5-1 | 284 | | 133 | 135 | −1.5% |
| | 6 | 6-1 | 280 | | 135 | 136 | −0.7% |
| | 7 | 7-1 | 310 | | 148 | 148 | 0.0% |
| | | 7-2 | 300 | | 141 | 143 | −1.4% |
| | | 7-3 | 315 | | 140 | 139 | 0.7% |
| | 8 | 8-1 | 258 | | 137 | 137 | 0.0% |
| | 9 | 9-1 | 290 | | 134 | 135 | −0.7% |
| | 10 | 10-1 | 250 | | 139 | 141 | −1.4% |
| Comparative | 4 | 4-2 | 233 | 250° C. × 1 hour | 88 | 91 | −3.4% |
| Examples | 11 | 11-1 | 302 | | 90 | 85 | 5.6% |
| | 12 | 12-1 | 235 | | 122 | 125 | −2.5% |
| | 13 | 13-1 | 241 | | 95 | 79 | 16.8% |
| | 14 | 14-1 | A crack was caused in extrusion step. | | | | |
| | | | Succeeding tests were not performed. | | | | |
| | 15 | 15-1 | 290 | 250° C. × 1 hour | 119 | 97 | 18.5% |
| | 16 | 16-1 | 231 | | 138 | 139 | −0.7% |
| | 17 | 17-1 | 284 | | 123 | 110 | 10.6% |
| | 18 | 18-1 | 227 | | 130 | 131 | −0.8% |
| | 19 | 19-1 | 292 | | 133 | 133 | 0.0% |
| | 20 | 20-1 | 247 | | 138 | 139 | −0.7% |
| | 21 | | 391 | | 88 | 54 | 38.6% |

| | | | | Maximum deformation amount after | | |
|---|---|---|---|---|---|---|
| | | | Crystal orientation of | sputtering test (mm) | | |
| | Alloy | Process | (200) plane in sliced | The number of times of detaching target | | |
| | No | No | cross section (%) | Once | Twice | Three times |
| Examples of | 1 | 1-1 | 63 | <0.2 | <0.2 | 0.2 |
| the present | 2 | 2-1 | 64 | <0.2 | <0.2 | <0.2 |
| invention | 3 | 3-1 | 66 | <0.2 | <0.2 | <0.2 |
| | 4 | 4-1 | 56 | <0.2 | <0.2 | <0.2 |
| | 5 | 5-1 | 57 | <0.2 | <0.2 | <0.2 |
| | 6 | 6-1 | 59 | <0.2 | <0.2 | <0.2 |
| | 7 | 7-1 | 61 | <0.2 | <0.2 | <0.2 |
| | | 7-2 | 55 | <0.2 | <0.2 | <0.2 |
| | | 7-3 | 59 | <0.2 | <0.2 | <0.2 |
| | 8 | 8-1 | 58 | <0.2 | <0.2 | <0.2 |
| | 9 | 9-1 | 54 | <0.2 | <0.2 | <0.2 |
| | 10 | 10-1 | 53 | <0.2 | <0.2 | <0.2 |
| Comparative | 4 | 4-2 | 60 | 0.2 | 0.35 | 0.4 |
| Examples | 11 | 11-1 | 70 | 0.2 | 0.3 | 0.5 |
| | 12 | 12-1 | 39 | <0.2 | 0.2 | 0.4 |
| | 13 | 13-1 | 52 | 0.2 | 0.2 | 0.5 |
| | 14 | 14-1 | | | | |
| | 15 | 15-1 | 41 | <0.2 | 0.2 | 0.4 |
| | 16 | 16-1 | 43 | <0.2 | <0.2 | 0.3 |
| | 17 | 17-1 | 44 | <0.2 | <0.2 | 0.4 |
| | 18 | 18-1 | 42 | <0.2 | <0.2 | 0.3 |
| | 19 | 19-1 | 42 | <0.2 | 0.3 | 0.4 |
| | 20 | 20-1 | 40 | <0.2 | <0.2 | 0.3 |
| | 21 | | | 0.4 | 0.5 | 0.8 |

⁽*⁾ The hardness decrease rate with a minus sign indicates that hardening of precipitates has progressed due to heating.

In Comparative Example 4-2 in which the composition of the alloy was within the range of the present invention but the heat treatment time was shorter than the range of the present invention, the thermal conductivity was less than 250 W/(m·K). In addition, the micro-Vickers hardness after heating treatment was performed in a condition of being held for one hour at 250° C. was less than 100 Hv, and the hardness and the heat resistance were insufficient. Therefore, the deformation amount after the first sputtering test increased.

In Comparative Example 11-1 in which the Co content was less than that of the range of the present invention, the mass ratio [Co]/[P] was lower than that of the range of the present invention, and the cross-sectional shrinkage ratio in the cold drawing step was higher than that of the range of the present invention, the micro-Vickers hardness after heating treatment was performed in a condition of being held for one hour at 250° C. was less than 100 Hv, the decrease rate from hardness before heating treatment exceeded 5%, and the hardness and the heat resistance were insufficient. Therefore, the deformation amount after the first sputtering test increased.

In Comparative Example 12-1 in which the Co content was more than that of the range of the present invention, the mass ratio [Co]/[P] was higher than that of the range of the present invention, and the cross-sectional shrinkage ratio in the cold drawing step was lower than that of the range of the present invention, the thermal conductivity was less than 250 W/(m·K). In addition, the crystal orientation of the (200) plane in a cross section orthogonal to the axial line was less than 50%, and the deformation amount after the second sputtering test increased.

In Comparative Example 13-1 in which the P content was less than that of the range of the present invention, the mass ratio [Co]/[P] was higher than that of the range of the present invention, and water cooling was not performed after the hot extruding step, the thermal conductivity was less than 250 W/(m·K). In addition, the micro-Vickers hardness after heating treatment was performed in a condition of being held for one hour at 250° C. was less than 100 Hv, the decrease rate from hardness before heating treatment exceeded 5%, and the hardness and the heat resistance were insufficient. Therefore, the deformation amount after the first sputtering test increased.

In Comparative Example 14 in which the P content was more than that of the range of the present invention and the mass ratio [Co]/[P] was lower than that of the range of the present invention, a crack was caused in the hot extruding step. Therefore, the succeeding steps and the evaluation stopped.

In Comparative Example 15-1 in which the Sn content was less than that of the range of the present invention and the temperature before hot working was lower than 850° C., when heating treatment was performed in a condition of being held for one hour at 250° C., the decrease rate from hardness before heating treatment exceeded 5%, and the heat resistance was insufficient. In addition, the crystal orientation of the (200) plane in a cross section orthogonal to the axial line was less than 50%. Therefore, the deformation amount after the second sputtering test increased.

In Comparative Example 16-1 in which the Sn content was more than that of the range of the present invention and the temperature before hot working was lower than 850° C., the thermal conductivity was less than 250 W/(m·K). In addition, the crystal orientation of the (200) plane in a cross section orthogonal to the axial line was less than 50%. Therefore, the deformation amount after the third sputtering test increased.

In Comparative Example 17-1 in which the Ni content was less than that of the range of the present invention and the cross-sectional shrinkage ratio in the cold drawing step was lower than that of the range of the present invention, when heating treatment was performed in a condition of being held for one hour at 250° C., the decrease rate from hardness before heating treatment exceeded 5% and the heat resistance was insufficient. In addition, the crystal orientation of the (200) plane in a cross section orthogonal to the axial line was less than 50%. Therefore, the deformation amount after the third sputtering test increased.

In Comparative Example 18-1 in which the Ni content was more than that of the range of the present invention and the cross-sectional shrinkage ratio in the cold drawing step was lower than that of the range of the present invention, the thermal conductivity was less than 250 W/(m·K). In addition, the crystal orientation of the (200) plane in a cross section orthogonal to the axial line was less than 50%. Therefore, the deformation amount after the third sputtering test increased.

In Comparative Example 19-1 in which the Zn content was less than that of the range of the present invention and the cross-sectional shrinkage ratio in the cold drawing step was lower than that of the range of the present invention, the crystal orientation of the (200) plane in a cross section orthogonal to the axial line was less than 50%. Therefore, the deformation amount after the second sputtering test increased.

In Comparative Example 20-1 in which the Zn content was more than that of the range of the present invention and the cross-sectional shrinkage ratio in the cold drawing step was lower than that of the range of the present invention, the thermal conductivity was less than 250 W/(m·K). In addition, the crystal orientation of the (200) plane in a cross section orthogonal to the axial line was less than 50%. Therefore, the deformation amount after the third sputtering test increased.

In Comparative Example 21 in which a raw tube formed of commercially available oxygen-free copper was used, the micro-Vickers hardness after heating treatment was performed in a condition of being held for one hour at 250° C. was less than 100 Hv, the decrease rate from hardness before heating treatment was 38.6% which was extremely significant, and the hardness and the heat resistance were insufficient. Therefore, the deformation amount after the first sputtering test extremely increased.

In contrast, according to Examples of the present invention, the thermal conductivity was 250 W/(m·K) or higher and the thermal conductivity was excellent. In addition, the micro-Vickers hardness after heating treatment was performed in a condition of being held for one hour at 250° C. was 100 Hv or higher, the decrease rate from hardness before heating treatment was 5% or less, and the hardness and the heat resistance was excellent. Therefore, the maximum deformation amount after the sputtering test was sufficiently restrained as well.

Consequently, according to Examples of the present invention, it was confirmed that a copper alloy backing tube which minimized deformation, was able to be repetitively used, had excellent heat radiation characteristics, and was able to cope with high-output sputtering deposition could be provided.

### INDUSTRIAL APPLICABILITY

According to the present invention, a copper alloy backing tube minimizes deformation of a backing tube, is able to be repetitively used, has excellent heat radiation characteristics, and is able to cope with high-output sputtering deposition.

### REFERENCE SIGNS LIST

10 cylindrical sputtering target
11 target material
12 copper alloy backing tube
13 bonding layer
14 surface plate

1. A copper alloy backing tube to be disposed on an inner circumferential side of a target material having a cylindrical shape in a cylindrical sputtering target, the copper alloy backing tube formed of,
a copper alloy having a composition containing,
0.10 mass % or more and 0.30 mass % or less of Co,
0.030 mass % or more and 0.10 mass % or less of P,
0.01 mass % or more and 0.50 mass % or less of Sn,
0.02 mass % or more and 0.10 mass % or less of Ni,
0.01 mass % or more and 0.10 mass % or less of Zn, and
a copper balance containing inevitable impurities,
wherein a mass ratio [Co]/[P] of a Co content [Co] to a P content [P] is within a range of 3.0 or higher and 6.0 or lower,
a thermal conductivity is 250 W/(m·K) or higher, and
a micro-Vickers hardness after a heating treatment is performed in a condition of being held for one hour at 250° C. is 100 Hv or higher, and a decrease rate from a hardness before the heating treatment is 5% or less.

2. The copper alloy backing tube according to claim 1,
wherein an orientation of a (200) plane in a cross section orthogonal to an axial line is 50% or more.

3. A method of manufacturing the copper alloy backing tube according to claim 1, the method comprising:
a melting and casting step of obtaining a copper alloy ingot having the composition;
a hot extruding step of obtaining a raw tube by heating the copper alloy ingot at a temperature of 850° C. or higher and performing extrusion working;
a fast rapid cooling step of rapidly cooling the raw tube after the hot extruding step;
a cold drawing step of performing drawing working of the obtained raw tube in a condition of a cross-sectional shrinkage ratio ranging of 10% or more and 70% or less; and
a heat treatment step of performing heat treatment of the raw tube after the cold drawing step in a condition where the raw tube is held for a period ranging of 1 hour or longer and 10 hours or shorter within a temperature range of 400° C. or higher and 600° C. or lower.

4. A method of manufacturing the copper alloy backing tube according to claim 2, the method comprising:
a melting and casting step of obtaining a copper alloy ingot having the composition;
a hot extruding step of obtaining a raw tube by heating the copper alloy ingot at a temperature of 850° C. or higher and performing extrusion working;
a fast rapid cooling step of rapidly cooling the raw tube after the hot extruding step;
a cold drawing step of performing drawing working of the obtained raw tube in a condition of a cross-sectional shrinkage ratio ranging of 10% or more and 70% or less; and
a heat treatment step of performing heat treatment of the raw tube after the cold drawing step in a condition where the raw tube is held for a period ranging of 1 hour or longer and 10 hours or shorter within a temperature range of 400° C. or higher and 600° C. or lower.
